(19) United States
(12) Patent Application Publication
(10) Pub. No.: US 2026/0358374 A1
(43) Pub. Date: Nov. 12, 2026

(54) Circuit Board Test Terminal

(71) Applicant: LG Energy Solution, Ltd., Seoul (KR)

(72) Inventor: Hye Jin Park, Daejeon (KR)

(73) Assignee: LG Energy Solution, Ltd., Seoul (KR)

(21) Appl. No.: 19/121,196

(22) PCT Filed: Sep. 22, 2023
(86) PCT No.: PCT/KR2023/014566

§ 371 Date: Apr. 15, 2025

(30) Foreign Application Priority Data
Oct. 17, 2022 (KR) 10-2022-0133602

(51) Int. Cl. G01R 1/073; G01R 31/28

(52) U.S. Cl. CPC G01R 1/07328; G01R 31/2863

(57) ABSTRACT

The present invention relates to a circuit board test terminal including a board part, and an extension part extending from the board part to be connected to a test point of a circuit board, wherein the board part includes: a plate unit that supports a lower portion; a partition unit disposed on the plate unit to divide the plate unit into a plurality of areas, and having a predetermined height; and a terminal unit disposed on each of the divided areas, wherein a test probe that tests the circuit board is in contact with the terminal unit.

### CROSS-REFERENCE TO RELATED APPLICATION

The present application is a national phase entry under 35 U.S.C. § 371 of International Application No. PCT/KR2023/014566, filed on Sep. 22, 2023, published in Korean, which claims priority to Korean Patent Application No. 10-2022-0133602, filed on Oct. 17, 2022, all of which are hereby incorporated by reference herein in their entireties.

### TECHNICAL FIELD

The present invention relates to a circuit board test terminal, and more particularly, to a terminal for testing an electronic component assembled with a circuit board.

### BACKGROUND ART

Printed circuit boards (PCB) are necessary parts used for almost every electronic equipment, and are printed circuit boards that are wired and provided on insulation plates so as to circuitally connect electric/electronic components. The PCBs each have a structure in which a conductor and an insulator are stacked in the form of a board, and a plurality of electric/electronic components such as semiconductors, capacitors, or resistors may be mounted thereon. The mounted electric/electronic components may be electrically connected to each other through an electric line circuit printed on the PCB. In the PCB, electric lines may be efficiently designed to reduce a size of an electronic equipment, and improve performance and productivity thereof.

The plurality of electric/electronic components mounted on the PCB may transmit or receive electrical signals. However, when an amount of electrical signals to be transmitted or received increases or high-speed processing of signals is required, a phenomenon in which a signal processing speed is decreased occurs, and this causes performance degradation of the PCB. In order to resolve the decrease in signal processing speed, methods such as a method of increasing the number of layers of the PCB to increase accommodating capacity for the components, are used.

Meanwhile, as it is difficult to check through the naked eyes whether the electronic components such as semiconductors, capacitors, or resistors, which are mounted on the PCB, are properly mounted on the PCB, a separate test device may be used to test whether the electronic components normally operate. When the test device is one, a worker may make a test right away with two hands by gripping a test probe with one hand to bring the test probe into contact with a target point on a circuit board, and gripping a ground probe with the other hand to bring the ground probe into contact with a ground point on the circuit board. However, if there are various types of test devices, testing with the test devices one by one as above causes problems that it takes much time to perform the testing, and results output by the test devices cannot be visually seen at a glance. In addition, when the testing is performed at once by connecting test probes to test points provided on the PCB, respectively, by using a method such as soldering so as to connect the various types of test devices to the target points on the circuit board at once, there are problems that the probes may be in contact with each other to cause an electrical short-circuit, and there is inconvenience to perform a separate process so as to remove the test probes having been connected through soldering or the like after the testing is performed.

Accordingly, there is a need for technical development to solve the problems as above.

### DISCLOSURE OF THE INVENTION

### Technical Problem

An object of the present invention for solving the above problems is to provide a circuit board test terminal capable of rapidly performing testing at once without an electrical short-circuit occurring between various types of test devices when an electronic component element, an electric circuit, or the like, which is mounted on a circuit board, is tested for whether to properly operate.

### Technical Solution

As one embodiment of the present invention, the present invention provides a circuit board test terminal including a board part, and an extension part extending from the board part to be connected to a test point of a circuit board, wherein the board part includes: a plate unit that supports a lower portion; a partition unit disposed on the plate unit to divide the plate unit into a plurality of areas, and having a predetermined height; and a terminal unit disposed on each of the divided areas, wherein a test probe that tests the circuit board is in contact with the terminal unit.

A holding groove having a predetermine depth may be defined in an upper end of the partition unit along an edge of the partition unit.

An inclination guide groove may be defined in a top surface of the terminal unit, wherein the inclination guide groove is a groove having a predetermined inclination to be inclined toward the holding groove defined in the partition unit adjacent thereto.

A vertical guide groove to which an end of the test probe is vertically inserted may be defined in the terminal unit.

The vertical guide groove may be defined in a central portion of the terminal unit.

The partition unit may include an electrical insulation material.

The extension part may include an extension unit having one end that is connected to the terminal unit, and a coupling unit coupled to the other end of the extension unit and coupled to the test point.

The coupling unit may be separated from and coupled to the extension unit.

The coupling unit may have an end having a ring shape.

The extension unit may be provided in plurality, and one end of each of a plurality of extension units may be connected to a different terminal unit. The coupling unit may be coupled to the other end of each of the extension units so as to be coupled to a plurality of test points.

The circuit board test terminal may further include a connecting unit that electrically connects the terminal unit to the extension unit, wherein the connecting unit is coupled to one side of the terminal unit.

As another embodiment of the present invention, the present invention may include a circuit board test terminal, and a test device including a test probe having an end, which is in contact with the circuit board test terminal, and a ground probe connected to a circuit board to be grounded, wherein the circuit board test terminal includes a board part, and an extension part extending from the board part to be connected to a test point of a circuit board, wherein the board part includes: a plate unit that supports a lower portion; a partition unit disposed on the plate unit to divide the plate unit into a plurality of areas, and having a predetermined height; and a terminal unit disposed on each of the divided areas, wherein a test probe that tests the circuit board is on contact with the terminal unit.

### Advantageous Effects

According to the present invention, when the electronic components mounted on the circuit board are tested for whether to normally operate, the various types of test devices may be simply connected to perform the testing at once so that the testing is rapidly performed. The testing may be performed at once through the various types of test devices to easily compare the values measured by the test devices. In addition, the test devices necessary for performing the testing may be rapidly separated even after the testing is performed.

### BRIEF DESCRIPTION OF THE DRAWINGS

FIG. 1 is a schematic plan view illustrating a board part according to the present invention.

FIG. 2 is a perspective view illustrating a state in which a test probe is held in each of an inclination guide groove and a holding groove in a portion A in FIG. 1.

FIG. 3 illustrates (a) a schematic cross-sectional view taken along line BB′ in FIG. 1 and (b) a schematic cross-sectional view taken along line CC′ in FIG. 1.

FIG. 4 is a schematic perspective view illustrating a state in which a terminal unit and an extension part are connected to each other through a connecting unit according to the present invention.

(a) to (d) of FIG. 5 are schematic views illustrating a coupling unit according various embodiments of the present invention.

FIG. 6 is a schematic perspective view illustrating a state in which an extension part is connected to an electronic component mounted on a circuit board according to the present invention.

FIG. 7 is a schematic plan view illustrating a circuit board test assembly according to an embodiment of the present invention.

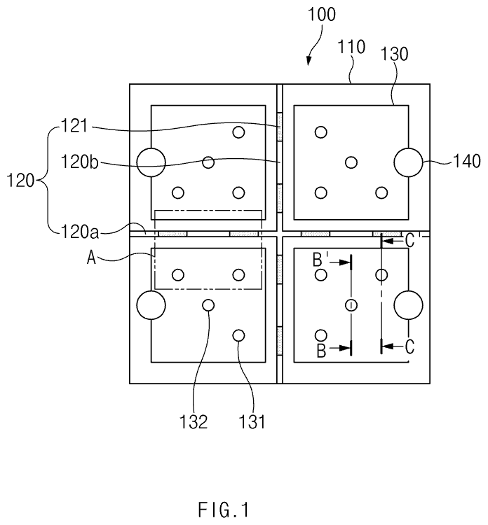

### MODE FOR CARRYING OUT THE INVENTION

Hereinafter, preferred embodiments of the present invention will be described in detail with reference to the accompanying drawings to enable those skilled in the art to which the present invention pertains to easily carry out the present invention. The present invention may, however, be embodied in different forms and should not be construed as limited by the embodiments set forth herein.

The parts unrelated to the description, or the detailed descriptions of related well-known art that may unnecessarily obscure subject matters of the present invention, will be ruled out in order to clearly describe the present invention. Like reference numerals refer to like elements throughout the whole specification.

Moreover, terms or words used in this specification and claims should not be restrictively interpreted as ordinary meanings or dictionary-based meanings, but should be interpreted as meanings and concepts conforming to the scope of the present invention on the basis of the principle that an inventor can properly define the concept of a term to describe and explain his or her invention in the best ways.

### Circuit Board Test Terminal (10)

As one embodiment of the present invention, the present invention relates to a circuit board test terminal 10 (hereinafter referred to as a “test terminal”), and the test terminal 10 may include a board part 100 and an extension part 150.

The board part 100 is a component to which a test probe 210 is connected, and the board part 100 may include a plate unit 110, a partition unit 120, and a terminal unit 130.

The plate unit 110 may have a flat shape having a predetermined area and thickness, and provide a bottom part of the test terminal 10.

The planar shape of the plate unit 110 may be, for example, a rectangular shape, a circular shape, or the like, but is not limited thereto.

The plate unit 110 may be disposed below the partition unit 120 and the terminal unit 130.

The plate unit 110 may be made of an electrical insulation material to prevent current from flowing between a lower portion of the plate unit 110 and the terminal unit 130. Accordingly, even when the board part 100 is moved to any position, the plate unit 110 may prevent electric noise from being introduced into the terminal unit 130 from a lower portion of the board part 100.

The partition unit 120 may be a wall having a small thickness, which is disposed on a top surface of the plate unit 110 and provided in a direction perpendicular to the top surface so as to divide the plate unit 110 into a plurality of areas.

The partition unit 120 may be made of an electrical insulation material to shield a plurality of terminal units 130 from each other so that a short-circuit is prevented from occurring.

As one embodiment, the partition unit 120 may include a horizontal part 120a and a vertical part 120b.

The horizontal part 120a may be disposed to be parallel to an edge of one surface of the plate unit 110 and the top surface of the plate unit 110, and divide the top surface of the plate unit 110 into a plurality of areas.

The horizontal part 120a may be provided in one or plurality, and a plurality of horizontal parts 120a may be disposed on the top surface of the plate unit 110 according to a predetermined interval or arrangement.

The vertical part 120b may be disposed in a direction perpendicular to the horizontal part 120a, or disposed to cross the horizontal part 120a at a predetermined angle.

A holding groove 121 may be defined in an upper end of the partition unit 120.

The holding groove 121 may be a groove having a predetermined depth, which is disposed along an edge of the upper end of the partition unit 120 in at least a partial region of the edge.

The shape of the holding groove 121 may be, for example, a faceted shape, a curved surface shape, or the like, but is not limited thereto.

The test probe 210 may be held in the holding groove 121. As an end of the test probe 210 is in contact with the terminal unit 130, and also a side surface part of the test probe 210 is in contact with the holding groove 121, the test probe 210 may be held in the holding groove 121 while forming a predetermined angle. A circuit board may be tested through the test probe 210 held in the holding groove 121, and while the test probe 210 is held in the holding groove 121, a worker may perform another work so that work efficiency is improved.

The terminal unit 130 may be disposed in each of the areas divided by the partition unit 120 on the plate unit 130.

The terminal unit 130 may include an electrically conductive metal material so as to be in contact with and electrically connected to the test probe 210. For example, the electrically conductive metal material may be copper, aluminum, gold, silver, or the like.

The terminal unit 130 may have an area and a shape corresponding to the shape of the area divided by the partition unit 120.

The terminal unit 130 may be provided in the form of a plate having a predetermined thickness and width in order to resolve inconvenience caused by testing in which the test probe 210 is in direct contact with a pin or the like of a very small electronic component 320 mounted on a circuit board 300 according to the related art. Thus, the worker may solely bring the test probe 210 into contact with the terminal unit 130 to obtain effects the same as those when the test probe 210 is in direct contact with the pin, a printed electric circuit, or the like of the very small electronic component 320, which is connected to the terminal unit 130 through and the extension part 150. In addition, the testing may be simply performed to remarkably improve the work efficiency.

An inclination guide groove 131 and a vertical guide groove 132 may be defined in the terminal unit 130.

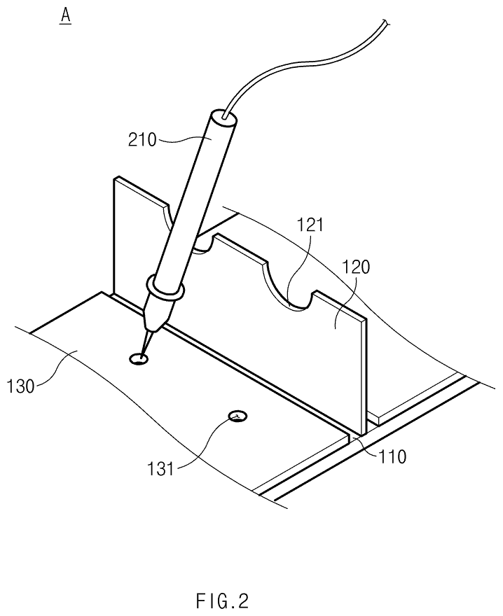

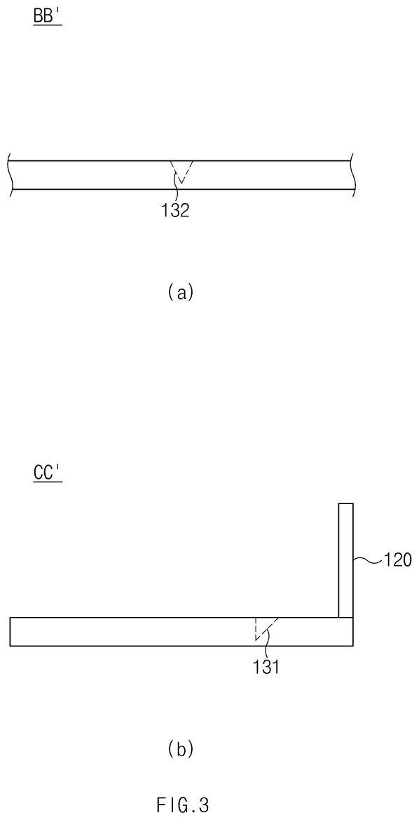

Referring to FIG. 2 and FIG. 3(b), the end of the test probe 210 may be inserted into the inclination guide groove 131 to increase a contact area between the test probe 210 and the terminal unit 130, and to provide an inclination in a direction, in which the test probe 210 is disposed, so that the test probe 210 is heled in the holding groove 121.

The inclination guide groove 131 may be defined to be spaced a predetermined distance from the partition unit 120 on a top surface of the terminal unit 130, and may be disposed to be more adjacent to an edge of the terminal unit 130 than the vertical guide groove 132.

Referring to FIG. 2 and FIG. 3(b), the inclination guide groove 131 may have a predetermined inclination inclined so that a virtual central line connecting a center of an opened top surface of the inclination guide groove 131 to a vertex of a lower end thereof faces the holding groove 121. Accordingly, as the end of the test probe 210 is inserted into the inclination guide groove 131, and the side surface part thereof is held in the holding groove 121, the test probe 210 may stand to be inclined at the predetermined angle. That is, the inclination guide groove 131 and the holding groove 210 corresponding to the inclination guide groove 131 may be disposed to be adjacent at a distance close to each other so that easy holding of the test probe 210 is achieved.

The inclination guide groove 131 may be provided in plurality to be disposed along the edge of the terminal unit 130. As a plurality of inclination guide groove 131 are disposed, a plurality of types of test probes 210 that measure different values from each other may be inserted at once into different inclination guide grooves 131, respectively, in one terminal unit 130, and the plurality of types of test probes 210 may measure at once values of the same electronic component 320 electrically connected to the terminal unit 130.

As the end of the test probe 210 is inserted and fixed to the inclination guide groove 131, a position of the test probe 210 held in the holding groove 121 may also be stably fixed.

Referring to (a) of FIG. 3, the vertical guide groove 132 may be defined in a central portion of the top surface of the terminal unit 130. The vertical guide groove 132 may be disposed so that a virtual central line connecting a center of an opened top surface of the vertical guide groove 132 to a vertex of a lower end thereof faces the center of the opened top surface.

Compared to the inclination guide groove 131, the vertical guide groove 132 may have a deeper depth, and the opened top surface thereof may have a smaller area so that when the end of the test probe 210 is inserted into the vertical guide groove 132, the test probe 210 stands in a direction perpendicular to the top surface of the terminal unit 130 even without being held in the holding groove 121.

As the vertical guide groove 132 and the inclination guide groove 131 are defined in one terminal unit 130, a plurality of types of test probes 210 that measure different values from each other may be inserted at once into inclination guide grooves 131 and vertical guide groove 132, respectively, and the plurality of types of test probes 210 may measure at once values of the same electronic component 320 electrically connected to the terminal unit 130.

The vertical guide groove 132 and the inclination guide groove 131 may be spaced a predetermined distance from each other so that the test probes 210 inserted into the vertical guide groove 132 and the inclination guide groove 131, respectively, are not in contact with each other. When contact between the test probes 210 occurs, current may flow even between the test probes 210 to cause an electrical short-circuit problem. As the vertical guide groove 132 and the inclination guide groove 131 are spaced a predetermined distance from each other to space the test probes 210, the problem as above may be prevented.

As the end of the test probe 210 is inserted into the vertical guide groove 132 and a position thereof is fixed, a position of the test probe 210 may also be stably fixed.

A connecting unit 140 may be disposed on one side of the terminal unit 130. and connect the terminal unit 130 to the extension part 150.

The connecting unit 140 may be coupled to the one side of the terminal unit 130. The coupling method may be, for example, a method of welding a lower end of the connecting unit 140 to one side of the top surface of the terminal unit 130, a method of screw-coupling the connecting unit 140 to one side of the terminal unit 130 through a spiral thread provided on a body of the connecting unit 140, or the like. However, the coupling method is not limited thereto.

The connecting unit 140 may electrically connect the terminal unit 130 to the extension part 150. The connecting unit 140 may include an electrically conductive metal material so as to electrically connect the terminal unit 130 to the extension part 150. For example, the connecting unit 140 may include a material such as copper, aluminum, silver, gold, or tungsten, but is not limited thereto.

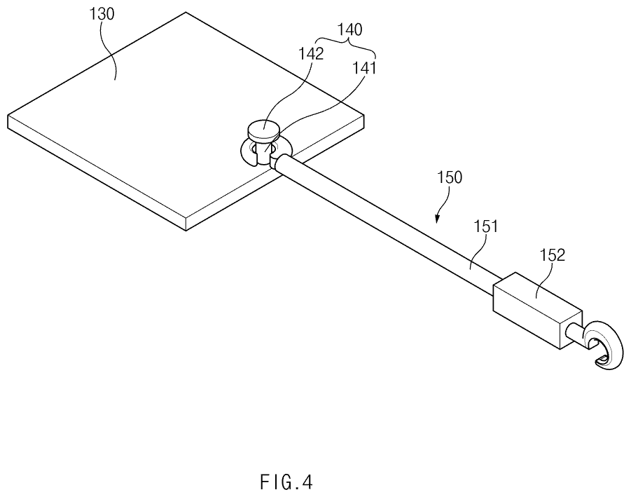

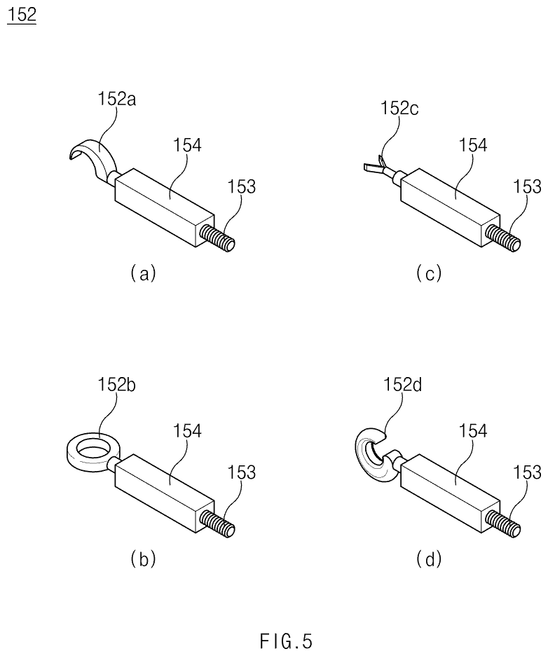

Referring to FIG. 4, the connecting unit 140 may include a body part 141, which is disposed in the direction perpendicular to the top surface of the terminal unit 130, and a head part 142 provided on an upper end of the body part 141. The body part 141 may have a shape such as a cylinder, a rectangular cylinder, or a faceted cylinder, and be coupled to an extension unit 151 of the extension part 150 so that the terminal unit 130 is coupled to the extension part 150.

The extension part 150 may include the extension unit 151 and a coupling unit 152.

The extension part 150 may freely space the board part 100 from the circuit board 300 so that the electronic component 320 or the like mounted on the circuit board 300 is tested using a test device 200 regardless of a position.

The extension unit 151 may have one end connected to the terminal unit 130, and the other end connected to the coupling unit 152. Specifically, the one end of the extension unit 151 may be connected to the body part of the connecting unit 140 coupled to the terminal unit 130.

Referring to FIG. 4, an annular structure made of an electrically conductive metal material may be provided on one end of the extension unit 151. The annular structure may be hooked with the body part 141 of the connecting unit 140 to rapidly connect the extension unit 151 to the connecting unit 140.

The extension unit 151 may include an extension line elongated in a direction from the annular structure provided on the one end to the other end. The extension line may include a metal layer (not shown) made of an electrically conductive material, which is connected to the annular structure provided on the one end of the extension unit 151, and an electrical insulation layer (not shown) which coats an outer surface of the metal layer with an electrical insulation material in a longitudinal direction thereof. A material of each of the metal layer and the electrical insulation layer of the extension line may be a plastically deformable material that is easily bent or has a curved surface provided thereon when force is applied thereto. For examples, the material of the metal layer may be copper, aluminum, or the like, and the material of the electrical insulation layer may be a natural rubber, a synthetic rubber, a synthetic resin, or the like.

The coupling unit 152 may be coupled to the other end of the extension unit 151.

The coupling unit 152 may be coupled to the extension unit 151 through a separable and couplable structure.

The coupling unit 152 may include a coupling part 153, a support 154, and each of ring parts 152a, 152b, 152c and 152d.

The coupling part 153 capable of coupled to the other end of the extension unit 151 may be provided on one end of the coupling unit 152. The coupling part 153 may be, for example, a bolt or the like, and the coupling part 153 may be coupled to the other end of the extension unit 151 through separable and couplable bolt coupling.

The support 154 may have one end provided with the coupling part 153, and the other end provided with each of the ring parts 152a, 152b, 152c and 152d.

The support 154 may be provided in the form of a faceted cylinder, for example, a rectangular cylinder, a pentagonal cylinder, or the like. As the support 154 has a shape of a faceted cylinder, the support 154 may be stably positioned without rolling on the circuit board 300. Thus, a position, at which each of the ring parts 152a, 152b, 152c and 152d is coupled to electronic components 320 on the circuit board 300, and a position adjacent thereto may be stably supported.

As the support 154 includes an electrical insulation material, current may not be allowed to flow to the coupling unit 152 through the support 154 even when the support 154 is in contact with other printed electric circuit or the like on the circuit board 300.

Hereinafter, the ring parts 152a, 152b, 152c and 152d according to various embodiments will be described with reference to FIG. 5.

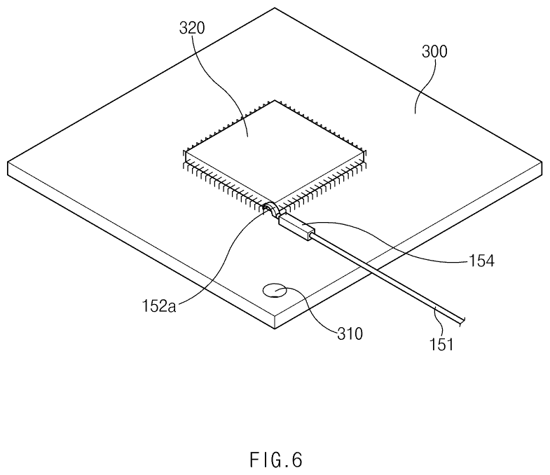

Referring to (a) of FIG. 5 and FIG. 6, as one embodiment of the present invention, a first ring part 152a may be provided on the other end of the coupling unit 152. The first ring part 152a may have a shape having a circumference that is at most half of a circumference of a circular ring. However, the first ring part 152a is not limited to the circular ring, and may have a shape of an oval ring or other closed curve ring. The first ring part 152a may have a structure capable of being easily hooked with a pin or the like of the electronic component 320 of the circuit board 300 so that the first ring part 152a is rapidly coupled. The first ring part 152a may be made of an electrically conductive metal material, and an outer surface thereof except an inner surface of the ring, which is in contact with the pin, may be coated with an electrical insulation material so as to prevent a short-circuit caused by contact with another pin adjacent to the pin.

Referring to (b) of FIG. 5, as another embodiment of the present invention, a second ring part 152b may be provided on the other end of the coupling unit 152. The second ring part 152b may have a shape of a circular ring. The second ring part 152b may be made of an electrically conductive metal material, and an outer surface thereof except an inner surface of the circular ring, which is in contact with a pin of the electronic component 320, may be coated with an electrical insulation material so as to prevent a short-circuit caused by contact with another pin adjacent to the pin.

Referring to (c) of FIG. 5, as still another embodiment of the present invention, a third ring part 152c may be provided on the other end of the coupling unit 152. The third ring part 152c may have a shape of a “V”- or “Y”-shaped ring. The third ring part 152c may be made of an electrically conductive metal material, and an outer surface thereof except an inner surface of the “V”- or “Y”-shaped ring, which is in contact with a pin of the electronic component 320, may be coated with an electrical insulation material so as to prevent a short-circuit caused by contact with another pin adjacent to the pin.

Referring to (d) of FIG. 5, as still another embodiment of the present invention, a fourth ring part 152d may be provided on the other end of the coupling unit 152. The fourth ring part 152d may have a shape having a circumference that is greater than half of a circumference of a circular ring. However, the fourth ring part 152d is not limited to the circular ring, and may have a shape of an oval ring or other closed curve ring. The fourth ring part 152d may be made of an electrically conductive metal material, and an outer surface thereof except an inner surface of the ring, which is in contact with a pin of the electronic component 320, may be coated with an electrical insulation material so as to prevent a short-circuit caused by contact with another pin adjacent to the pin.

### Circuit Board Test Assembly (20)

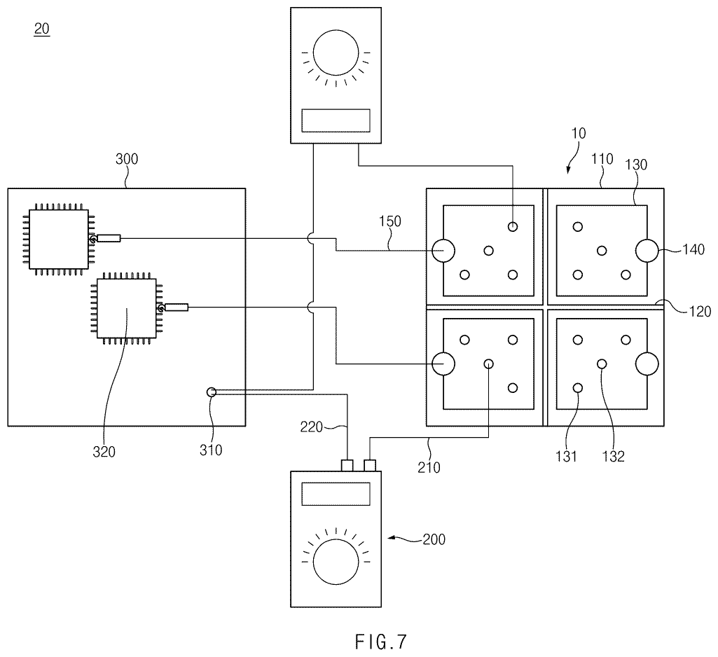

Referring to FIG. 7, a circuit board test assembly 20 may include a circuit board test terminal 10 and a test device 200. The test device 200 may include a test probe 210 having one end, which is in contact with a terminal unit 130 of the circuit board test terminal 10, and a ground probe 220 having one end which is connected to a ground point 310 of a circuit board 300 so as to be grounded.

As the ground probe 220 is grounded, the test device 200 may set a reference value for values measured by the test probe 210, and reduce noise from being introducing into the test probe 210. Accordingly, reliability of the values measured by the test probe 210 may be improved.

The test probe 210 may be in contact with a terminal unit 130 to test whether an electronic component 320, a printed electric circuit, or the like, which is electrically connected to the circuit board test terminal 10, operates normally on the circuit board 300.

The circuit board 300 may include various types of circuit boards, for example, a printed circuit board (PCB), a flexible printed circuit board (FPCB), a rigid-flexible printed circuit board (RF-PCB), and a high density interconnection (HDI) board, and preferably, the circuit board 100 may be a PCB circuit board. However, the circuit board 100 is not limited thereto.

Each of the electronic components 320 in which an electric circuit is printed through printed electronics may be mounted at a predetermined position on the circuit board 300.

The specific description of the circuit board test terminal 10 may be replaced with the content described above.

Although the present invention has been described with reference to the limited embodiments and drawings, the present invention is not limited thereto and may be variously implemented by those of ordinary skill in the art to which the present invention pertains, within the technical idea of the present invention and an equivalent of the appended claims.

### DESCRIPTION OF THE SYMBOLS

10: Circuit board test terminal
20: Circuit board test assembly
100: Board part
110: Plate unit
120: Partition unit
120: Horizontal part
120: Vertical part
121: Holding groove
130: Terminal unit
131: Inclination guide groove
132: Vertical guide groove
140: Connecting unit
150: Extension part
151: Extension unit
152: Coupling unit
200: Test device
210: Test probe
300: Circuit board
310: Ground point
320: Electronic component

1. A circuit board test terminal comprising:
a board part; and
an extension part extending from the board part and configured to be connected to a test point of a circuit board,
wherein the board part comprises:
a plate unit configured to support a lower portion of the board part;
a partition unit disposed on the plate unit, the partition unit dividing the plate unit into a plurality of areas, the partition unit having a predetermined height; and
a plurality of terminal units each disposed on a respective one of the plurality of areas,
wherein a test probe configured to test the circuit board is in contact with one of the terminal units.

2. The circuit board test terminal of claim 1, wherein an upper end of the partition unit has a holding groove having a predetermine depth defined therein along an edge of the partition unit.

3. The circuit board test terminal of claim 2, wherein a top surface of each terminal unit has an inclination guide groove defined therein the inclination guide groove being a groove having a predetermined inclination toward the holding groove.

4. The circuit board test terminal of claim 1, wherein each terminal unit has a vertical guide groove into which an end of the test probe is vertically inserted defined therein.

5. The circuit board test terminal of claim 4, wherein the vertical guide groove is defined in a central portion of the terminal unit.

6. The circuit board test terminal of claim 1, wherein the partition unit comprises an electrical insulation material.

7. The circuit board test terminal of claim 1, wherein the extension part comprises:
a first extension unit having a first end that is connected to one of the terminal units; and
a coupling unit coupled to a second end of the first extension unit and coupled to the test point.

8. The circuit board test terminal of claim 7, wherein the coupling unit is separated from and coupled to the first extension unit.

9. The circuit board test terminal of claim 7, wherein the coupling unit has an end having a ring shape.

10. The circuit board test terminal of claim 7, wherein the extension part has a plurality of extension units including the first extension unit, and a first end of each the extension units is connected to a different one of the terminal units, and the coupling unit is coupled to a second end of each of the extension units so as to be coupled to a plurality of test points.

11. The circuit board test terminal of claim 7, further comprising a connecting unit configured to electrically connect one of the terminal units to the first extension unit, wherein the connecting unit is coupled to one side of the one of the terminal units.

12. A circuit board test assembly comprising:
a circuit board test terminal; and
a test device comprising a test probe having an end, in contact with the circuit board test terminal; and a ground probe connected to a circuit board to be grounded,
wherein the circuit board test terminal comprises:
a board part; and
an extension part extending from the board part and configured to be connected to a test point of a circuit board,
wherein the board part comprises:
a plate unit configured to support a lower portion of the board part;
a partition unit disposed on the plate unit, the partition unit dividing the plate unit into a plurality of areas, the partition unit having a predetermined height; and
a plurality of terminal units each disposed on a respective one of the plurality of areas,
wherein a test probe configured to test the circuit board is in contact with one of the terminal units.
